(19) United States
(12) Patent Application Publication
(10) Pub. No.: US 2023/0121551 A1
(43) Pub. Date: Apr. 20, 2023

(54) METHOD OF ANALYZING CONTAMINANTS ON SUBSTRATE AND METHOD OF TREATING SUBSTRATE

(71) Applicant: SEMES CO., LTD., Chungcheongnam-do (KR)

(72) Inventor: Da Jeong KIM, Seoul (KR)

(21) Appl. No.: 17/965,820

(22) Filed: Oct. 14, 2022

(30) Foreign Application Priority Data
Oct. 18, 2021 (KR) 10-2021-0138252

(51) Int. Cl. G01N 21/65

(52) U.S. Cl. CPC G01N 21/658

(57) ABSTRACT

Provided is a method of analyzing contaminants adsorbed to a surface of a substrate, the method including: a substrate treating operation of performing a process on a substrate; an operation of introducing a surface-enhanced Raman scattering layer to the substrate having the surface to which a contaminant is adsorbed substrate in the substrate treating operation; and an operation of analyzing the contaminant.

### CROSS-REFERENCE TO RELATED APPLICATIONS

This application claims priority to and the benefit of Korean Patent Application No. 10-2021-0138252 filed in the Korean Intellectual Property Office on Oct. 18, 2021, the entire contents of which are incorporated herein by reference.

### TECHNICAL FIELD

The present invention relates to a method of analyzing contaminants on a substrate, and a method of treating a substrate.

### BACKGROUND ART

In general, in order to manufacture a semiconductor device, a desired pattern is formed on a substrate through various processes, such as photography, etching, ashing, ion implantation, and thin film deposition. In each process, various processing liquids are used, and particles, such as contaminants, are generated during the process. In order to remove the particles, a cleaning process for cleaning the particles is performed before and after each process.

The particles adsorbed to the substrate greatly affect the yield of the device, and directly or indirectly affect the device and the element, such as causing a short circuit of the semiconductor device and deterioration or defect of a gate oxide film. Accordingly, in order to remove particles or control the generation of particles, it is required to analyze the components and structures of the particles. Particles are divided into metal contaminants and organic contaminants according to the type of processing liquid used in the substrate treating process. Among the mentioned particles, various analysis devices and methods have been developed for metal contaminants, and it is possible to analyze metal contaminants present in trace amounts on a substrate.

General methods of analyzing organic contaminants on the substrate include IR spectroscopy, Time of Flight Secondary Ion Mass Spectrometry (ToF-SIMS), Electron Spectroscope for Chemical Analysis (ESCA), and Gas Chromatography-Mass Spectrometer (GC-MS).

Infrared spectroscopy may measure and analyze organic contaminants by using the surface of a substrate as a sample. IR spectroscopy analyzes the organic contaminants through the inherent spectrum of the material generated from the organic contaminants on the substrate by emitting infrared rays to the substrate. However, IR spectroscopy has a problem in that it is difficult to detect trace amounts of organic contaminants present on a substrate due to low signal generation efficiency.

ToF-SIMS, ESCA, and GC-MS can analyze the substrate surface as a sample. ToF-SIMS, ESCA, and GC-MS require expensive analysis costs, and can analyze only the element included in organic contaminants, but have difficulty in analyzing the structure of organic contaminants.

### SUMMARY OF THE INVENTION

The present invention has been made in an effort to provide a method of analyzing contaminants and a method of treating a substrate capable of rapidly and accurately detecting and analyzing organic contaminants on a substrate.

The present invention has been made in an effort to provide a method of analyzing contaminants and a method of treating a substrate capable of analyzing a composition, a structure, and the degree of distribution of organic contaminants on a substrate.

The object of the present invention is not limited thereto, and other objects not mentioned will be clearly understood by those of ordinary skill in the art from the following description.

An exemplary embodiment of the present invention provides a method of analyzing contaminants adsorbed to a surface of a substrate, the method including: a substrate treating operation of performing a process on a substrate; an operation of introducing a surface-enhanced Raman scattering layer to the substrate having the surface to which a contaminant is adsorbed substrate in the substrate treating operation; and an operation of analyzing the contaminant.

Another exemplary embodiment of the present invention provides a method of analyzing contaminants adsorbed to a surface of a substrate, the method including: an operation of introducing a surface-enhanced Raman scattering layer to a surface of a substrate; a substrate treating operation of performing a process on the substrate to which the surface-enhanced Raman scattering layer is introduced; and an operation of analyzing the contaminant adsorbed to the substrate in the substrate treating operation.

The operation of analyzing the contaminant may be performed by Raman analysis.

The operation of analyzing the contaminant may include: emitting first light to the substrate; detecting second light generated from the contaminant and amplified by the surface-enhanced Raman scattering layer; and analyzing the contaminant by analyzing the second light.

In the operation of analyzing the contaminant, a molecular structure of the contaminant may be analyzed.

The surface-enhanced Raman scattering layer may be formed by depositing a surface-enhanced Raman scattering material, and the surface-enhanced Raman scattering material may be provided as a metal material with high conductivity capable of generating surface plasmon excitation.

The surface-enhanced Raman scattering material may include at least one of gold (Au), silver (Ag), aluminum (Al), copper (Cu), nickel (Ni), iron (Fe), cobalt (Co), zinc (Zn), titanium (Ti), ruthenium (Ru), rhodium (Rh), palladium (Pd), platinum (Pt), osmium (Os), iridium (Ir), and molybdenum (Mo).

The surface-enhanced Raman scattering layer may be provided in a nanostructure.

The nanostructure may include any one of a nanoparticle, a nanorod, and a nanopattern.

The contaminant may be provided as an organic material.

In the substrate treating operation, the substrate may be treated by supplying a processing liquid to the substrate, and the processing liquid may be provided as a liquid containing an organic material.

In the substrate treating operation, a photo process or a clean process may be performed on the substrate.

The substrate treating operation and the operation of introducing the surface-enhanced Raman scattering layer may be performed in different chambers.

Still another exemplary embodiment of the present invention provides a method of treating a substrate, the method including: treating a substrate by supplying a processing liquid to the substrate, in which before or after the treating of the substrate, a surface-enhanced Raman scattering layer is introduced by depositing a surface-enhanced Raman scattering material on a surface of the substrate.

The surface-enhanced Raman scattering material may be provided as a metal material with high conductivity capable of generating surface plasmon excitation.

The surface-enhanced Raman scattering material may include at least one of gold (Au), silver (Ag), aluminum (Al), copper (Cu), nickel (Ni), iron (Fe), cobalt (Co), zinc (Zn), titanium (Ti), ruthenium (Ru), rhodium (Rh), palladium (Pd), platinum (Pt), osmium (Os), iridium (Ir), and molybdenum (Mo).

The processing liquid may be provided as a liquid containing an organic material.

The treatment of the substrate may include photo processing or cleaning processing.

The substrate treatment and the introduction of the surface-enhanced Raman scattering layer may be performed in different chambers.

A contaminant generated during the process of treating the substrate may be adsorbed to the surface of the substrate or the surface-enhanced Raman scattering layer, a structure of the contaminant may be analyzed by Raman analysis, and the surface-enhanced Raman scattering layer may amplify a Raman signal of the contaminant.

According to the exemplary embodiment of the present invention, it is possible to quickly and accurately detect and analyze organic contaminants on a substrate.

Further, according to the exemplary embodiment of the present invention, it is possible to analyze a composition, a structure, and the degree of distribution of organic contaminants on a substrate.

Further, according to the exemplary embodiment of the present invention, it is possible to detect and analyze organic contaminants by using a substrate itself on which the organic contaminants are adsorbed as a sample.

Further, according to the exemplary embodiment of the present invention, it is possible to maximize the analytical detection limit of organic contaminants on a surface of a substrate.

Further, according to the exemplary embodiment of the present invention, since pretreatment for component analysis of organic contaminants is not required, it is possible to minimize the possibility of contamination of a substrate due to the pretreatment.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a flowchart of a method of analyzing contaminants on a substrate according to an exemplary embodiment of the present invention.

FIGS. 2 to 5 are diagrams schematically illustrating a process of performing the analysis method of FIG. 1.

FIG. 6 is a flowchart of a method of analyzing contaminants on a substrate according to another exemplary embodiment of the present invention.

FIGS. 7 to 11 are diagrams schematically illustrating a process of performing the analysis method of FIG. 6.

FIG. 12 is a diagram schematically illustrating a process of detecting a contaminant adsorbed to a surface-enhanced Raman scattering layer in the analysis method according to FIGS. 1 and 6.

### DETAILED DESCRIPTION

Hereinafter, an exemplary embodiment of the present invention will be described more fully hereinafter with reference to the accompanying drawings, in which exemplary embodiments of the invention are illustrated. However, the present invention can be variously implemented and is not limited to the following exemplary embodiments. In addition, in describing an exemplary embodiment of the present invention in detail, if it is determined that a detailed description of a related well-known function or configuration may unnecessarily obscure the gist of the present invention, the detailed description thereof will be omitted. In addition, the same reference numerals are used throughout the drawings for parts having similar functions and actions.

In addition, unless explicitly described to the contrary, the word “comprise” and variations such as “comprises” or “comprising” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

The exemplary embodiment of the present invention may be modified in various forms, and the scope of the present invention should not be construed as being limited to the following exemplary embodiments. The present exemplary embodiment is provided to more completely explain the present invention to those skilled in the art. Therefore, the shapes of elements in the drawings are exaggerated to emphasize clearer descriptions.

Here, the substrate is a comprehensive concept including all substrates used for manufacturing semiconductor devices, Flat Panel Displays (FPDs), and other articles in which circuit patterns are formed on thin films. Examples of the substrate W include a silicon wafer, a glass substrate, and an organic substrate.

Hereinafter, an exemplary embodiment of the present invention will be described in detail with reference to the drawings.

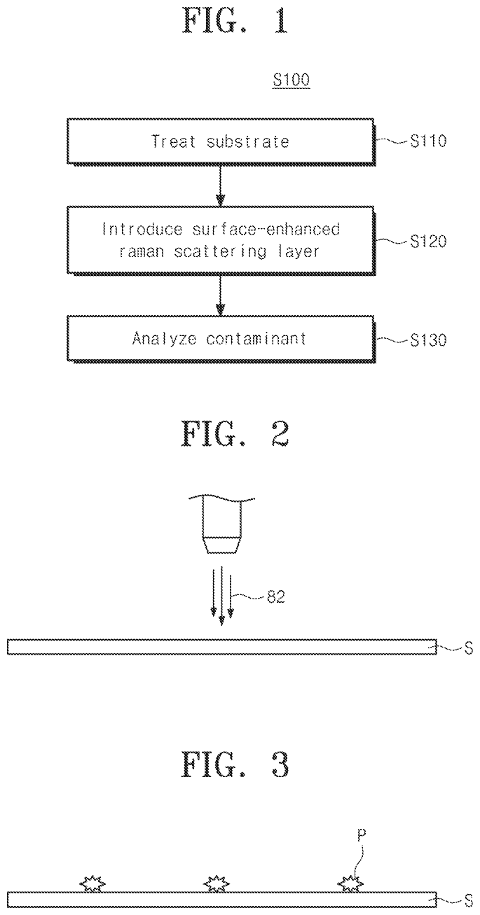

FIG. 1 is a flowchart of a method of analyzing contaminants on a substrate according to an exemplary embodiment of the present invention, FIGS. 2 to 5 are diagrams schematically illustrating a process of performing the analysis method of FIG. 1, and FIG. 12 is a diagram schematically illustrating a process of detecting a contaminant adsorbed to a surface-enhanced Raman scattering layer in the analysis method according to FIGS. 1 and 6.

Referring to FIG. 1, a method S100 for analyzing contaminants on a substrate according to an exemplary embodiment of the present invention includes a substrate treating operation S110 of performing a process on a substrate S, an operation S120 of introducing a Surface-Enhances Raman Scattering (SERS) layer M to the substrate S on which process contaminants P generated in the substrate treating operation S110 are adsorbed, and an operation S130 of analyzing the contaminant P.

FIG. 2 is a diagram schematically illustrating the substrate treating operation S110 in the method S100 of analyzing the contaminants on the substrate according to the exemplary embodiment of the present invention, and FIG. 3 is a diagram illustrating the state where the contaminants P are adsorbed to the surface of the substrate S by the substrate treating operation S110 of FIG. 2.

Referring to FIG. 2, in the substrate treating operation S110, the substrate S is treated by supplying a processing liquid 82 to the substrate S. The processing liquid 82 is provided as a liquid containing an organic material. The processing process performed on the substrate S in the substrate treating operation S110 includes an organic process. For example, in the substrate treating operation S110, a photo process for supplying photoresist to the substrate S may be performed. As another example, in the substrate treating operation S110, a clean process of supplying chemicals, such as sulfuric acid and phosphoric acid, to the substrate S may be performed. However, the present invention is not limited thereto, and various processes in which the processing liquid 82 including the organic material is supplied to the substrate S may be performed in the substrate treating operation S110.

Referring to FIG. 3, the contaminant P may be adsorbed to the surface of the substrate S in the process of treating the substrate S in the substrate treating operation S110. The amount of generated contaminants P may vary depending on the process environment, the type of the processing liquid 82, the material of the chamber in which the process is performed, and the like. In general, since the substrate treating process is performed in a clean room in which a clean downdraft is continuously supplied, the contaminants P according to the process is generated in a very small amount. The contaminants P include organic contaminants. The contaminant P may be determined according to the type of process performed in the substrate treating operation S110. Alternatively, the contaminant P may be determined according to the material of the chamber in which the substrate treating operation S110 is performed.

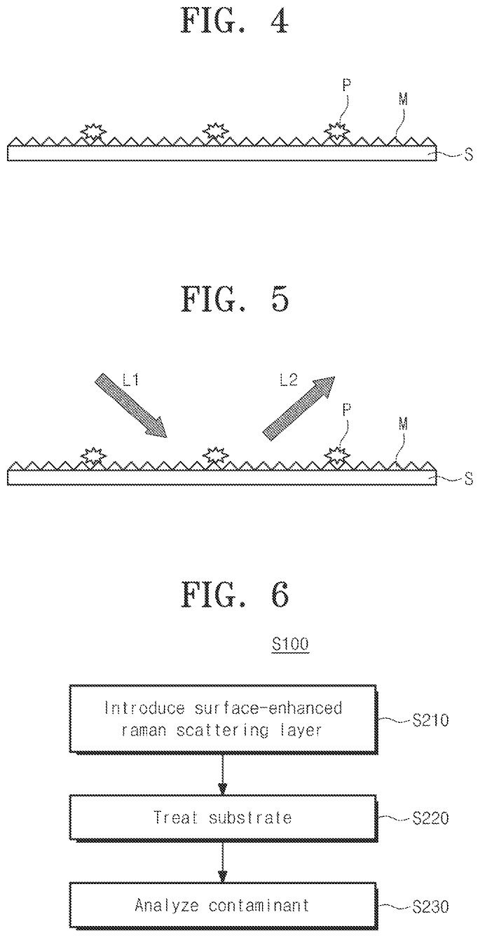

FIG. 4 is a diagram schematically illustrating the surface-enhanced Raman scattering layer introduction operation S120 of introducing a surface-enhanced Raman scattering layer to the substrate S on which the contaminant P of FIG. 3 is adsorbed.

Referring to FIG. 4, in the surface-enhanced Raman scattering layer introduction operation S120, a surface-enhanced Raman scattering (SERS) material is deposited on the substrate S on which the contaminant P is adsorbed to form a surface-enhanced Raman scattering layer M. The surface-enhanced Raman scattering material may refer to a material having a surface-enhanced Raman scattering effect. The enhanced Raman scattering material may be provided as a highly conductive metal material capable of generating surface plasmon excitation. For example, the surface-enhanced Raman scattering material may include any one metal among gold (Au), silver (Ag), aluminum (Al), copper (Cu), nickel (Ni), iron (Fe), cobalt (Co), zinc (Zn), titanium (Ti), ruthenium (Ru), rhodium (Rh), palladium (Pd), platinum (Pt), osmium (Os), iridium (Ir), and molybdenum (Mo). For example, the surface-enhanced Raman scattering material may be provided as a noble metal-based metal. For example, the surface-enhanced Raman scattering material may include an alloy or a compound including at least one of gold (Au), silver (Ag), aluminum (Al), copper (Cu), nickel (Ni), iron (Fe), cobalt (Co), zinc (Zn), titanium (Ti), ruthenium (Ru), rhodium (Rh), palladium (Pd), platinum (Pt), osmium (Os), iridium (Ir), and molybdenum (Mo). By introducing the surface-enhanced Raman scattering layer M, a Raman scattering signal that is difficult to be detected due to a weak signal may be amplified.

The surface-enhanced Raman scattering layer M may be provided as a thin film. The surface-enhanced Raman scattering layer M may be provided in a nanostructure. The nanostructure may be formed by arranging a plurality of nanoparticles. The size of the nanoparticles may be smaller than the wavelength of first light L1 emitted to the substrate S. The nanostructure may be formed by arranging a plurality of nanoparticles spaced apart from each other at regular intervals. The nanostructure may be formed by arranging a plurality of nanoparticles in a specific pattern. The surface-enhanced Raman scattering layer M may be formed by depositing the surface-enhanced Raman scattering material on the surface of the substrate S as nano-sized particles. The nanoparticles may include spherical nanoparticles and rod-shaped nanorods. However, the present invention is not limited thereto and may be provided as particles of various shapes, such as a triangular pyramid shape.

The substrate treating operation S110 and the surface-enhanced Raman scattering layer introduction operation S120 are performed in different chambers. However, the present invention is not limited thereto, and the substrate treating operation S110 and the surface-enhanced Raman scattering layer introduction operation S120 may be performed in the same chamber.

Surface plasmon excitation is a characteristic of nano-sized metals, and is a phenomenon of collective vibration of electrons generated by the interaction between photons and electrons when light is emitted onto the surface of nano-sized metal. As the surface-enhanced Raman scattering material is provided as a material capable of generating surface plasmon excitation, it is possible to amplify the Raman signal.

FIG. 5 schematically illustrates the contaminant analysis operation S130 in which the contaminant analysis is performed on the substrate S on which the contaminant P is adsorbed and the surface-enhanced Raman scattering layer M is introduced of FIG. 4.

The contaminant analysis operation S130 is performed by Raman analysis. The contaminant analysis operation S130 is performed by Raman spectroscopy. The contaminant analysis operation S130 is performed by surface-enhanced Raman scattering spectroscopy. In the contaminant analysis operation S130, the molecular structure of the contaminant P may be analyzed. In addition, in the contaminant analysis operation S130, a component, a composition ratio of the contaminant P, or the degree of distribution of the contaminant P on the surface of the substrate S may be analyzed.

The contaminant analysis operation S130 includes is emitting the first light L1 to the substrate S, detecting second light L2 generated from the contaminant P and amplified by the surface-enhanced Raman scattering layer M, and analyzing a component, a molar ratio of molecules, a molecular structure, and the like of the contaminant P by analyzing the second light L2.

Referring to FIGS. 5 and 12, the first light L1 is emitted to the substrate S. When the first light L1 is emitted, the first light L1 and the molecules of the contaminant P interact with each other, and photons of the first light L1 are scattered. At this time, the degree of scattering of the photons of the first light L1 varies according to the molecular identity of the molecules constituting the contaminant P, and the kinetic energy of the photons of the first light L1 is increased or decreased by scattering.

The first light L1 is changed into the second light L2 having different characteristics from the first light L2 by scattering. For example, the wavelength of the first light L2 may be different from the wavelength of the second light L2. In this case, the change in wavelength may be increased or decreased by the molecules constituting the contaminant P. A wavenumber of the first light L2 may be different from a wavenumber of the second light L2. The wavenumber means the reciprocal of the wavelength, and the change in the wavenumber may be increased or decreased by the molecules constituting the contaminant P. The energy of the first light L2 may be different from the energy of the second light L2. In this case, the change in energy may be increased or decreased by the molecules constituting the contaminant P.

In the second light L2, signals, such as wavelength, wavenumber, and energy, may be amplified by the surface-enhanced Raman scattering layer M. The second light L2 includes a Raman scattering signal, and accordingly, the second light L2 may be referred to as a Raman scattering signal. In addition, the Raman scattering signal is amplified by the surface-enhanced Raman scattering layer M, which may be referred to as a Raman scattering amplified signal.

In the contaminant analysis operation S130, the contaminant P is analyzed by detecting the second light L2 or the Raman scattering amplified signal from the second light L2. In the contaminant analysis operation S130, a component of a material constituting the contaminant P, a bonding structure of the contaminant P, etc. may be analyzed through the second light L2 or the Raman scattering amplified signal detected from the second light L2.

The first light L1 may be emitted to the substrate S by an optical system, such as a laser, and the second light L2 may be detected through a detector, such as a sensor. The analysis of the contaminant P may be performed through a controller (not illustrated). Configuration, storage and management of the controller may be realized in the form of hardware, software, or a combination of hardware and software. The file data and/or the software configuring the controller may be stored in volatile or non-volatile storage devices, such as Read Only Memory (ROM); or memory, such as, for example, Random Access Memory (RAM), memory chips, devices, or integrated circuits, or a storage medium, such as Compact Disk (CD), Digital Versatile Disc (DVD), magnetic disk, or magnetic tape, which are optically or magnetically recordable and simultaneously machine (for example, computer)-readable.

Hereinafter, another exemplary embodiment of the present invention will be described in detail with reference to the drawings.

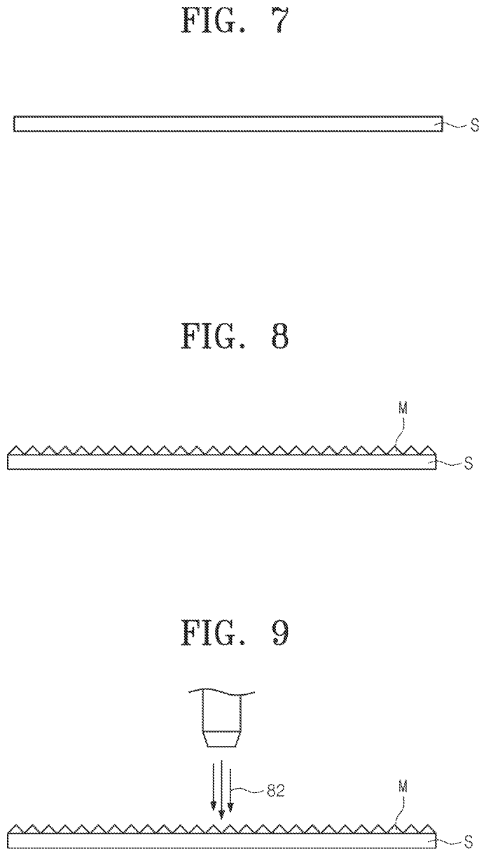

FIG. 6 is a flowchart of a method of analyzing contaminants on a substrate according to another exemplary embodiment of the present invention, FIGS. 7 to 11 are diagrams schematically illustrating a process of performing the analysis method of FIG. 6, and FIG. 12 is a diagram schematically illustrating a process of detecting a contaminant adsorbed to a surface-enhanced Raman scattering layer in the analysis method according to FIGS. 1 and 6.

Referring to FIG. 6, a method S200 of analyzing contaminants on a substrate according to another exemplary embodiment of the present invention includes an operation S210 of introducing a surface-enhanced Raman scattering layer M on a surface of a substrate S, a substrate treating operation S220 of performing a process on the substrate S to which the surface-enhanced Raman scattering layer M is introduced, and an operation of analyzing a contaminant P generated in the substrate treating operation S220.

The method S200 of analyzing contaminants according to another exemplary embodiment of the present invention is different from the method S100 of analyzing contaminants according to the exemplary embodiment in a process sequence. Specifically, in the method S100 of analyzing contaminants according to the exemplary embodiment, the surface-enhanced Raman scattering layer introduction operation S120 is performed after the substrate treating operation S110, but in the method S200 of analyzing contaminants according to another exemplary embodiment, the substrate treating operation S220 is performed after the surface-enhanced Raman scattering layer introduction operation S210.

FIG. 7 is a diagram illustrating the substrate S on which no treatment is performed, and FIG. 8 is a diagram illustrating the substrate S to which the surface-enhanced Raman scattering layer is introduced for the substrate S of FIG. 7.

Referring to FIGS. 7 and 8, unlike the method S100 of analyzing contaminants according to the exemplary embodiment of the present invention, the surface-enhanced Raman scattering layer M is introduced on the substrate S before the substrate treating operation S220 is performed. In the surface-enhanced Raman scattering layer introduction operation S210, a surface-enhanced Raman scattering (SERS) material is deposited on the substrate S to form a surface-enhanced Raman scattering layer M. The surface-enhanced Raman scattering material may refer to a material having a surface-enhanced Raman scattering effect. The enhanced Raman scattering material may be provided as a highly conductive metal material capable of generating surface plasmon excitation. For example, the surface-enhanced Raman scattering material may include any one metal among gold (Au), silver (Ag), aluminum (Al), copper (Cu), nickel (Ni), iron (Fe), cobalt (Co), zinc (Zn), titanium (Ti), ruthenium (Ru), rhodium (Rh), palladium (Pd), platinum (Pt), osmium (Os), iridium (Ir), and molybdenum (Mo). For example, the surface-enhanced Raman scattering material may be provided as a noble metal-based metal. For example, the surface-enhanced Raman scattering material may include an alloy or a compound including at least one of gold (Au), silver (Ag), aluminum (Al), copper (Cu), nickel (Ni), iron (Fe), cobalt (Co), zinc (Zn), titanium (Ti), ruthenium (Ru), rhodium (Rh), palladium (Pd), platinum (Pt), osmium (Os), iridium (Ir), and molybdenum (Mo). By introducing the surface-enhanced Raman scattering layer M, a Raman scattering signal that is difficult to be detected due to a weak signal may be amplified.

The surface-enhanced Raman scattering layer M may be provided as a thin film. The surface-enhanced Raman scattering layer M may be provided in a nano structure. The nanostructure may be formed by arranging a plurality of nanoparticles. The size of the nanoparticles may be smaller than the wavelength of first light L1 emitted to the substrate S. The nanostructure may be formed by arranging a plurality of nanoparticles spaced apart from each other at regular intervals. The nanostructure may be formed by arranging a plurality of nanoparticles in a specific pattern. The surface-enhanced Raman scattering layer M may be formed by depositing the surface-enhanced Raman scattering material on the surface of the substrate S as nano-sized particles. The nanoparticles may include spherical nanoparticles and rod-shaped nanorods. However, the present invention is not limited thereto and may be provided as particles of various shapes, such as a triangular pyramid shape.

FIG. 9 is a diagram illustrating a process in which the substrate treating operation is performed on the substrate S to which the surface-enhanced Raman scattering layer of FIG. 8 is introduced. In the process of treating the substrate S in the substrate treating operation S220, the contaminant P may be adsorbed to the surface of the substrate S or the surface-enhanced Raman scattering layer M. The amount of generated contaminants P may vary depending on the process environment, the type of the processing liquid 82, the material of the chamber in which the process is performed, and the like. In general, since the substrate treating process is performed in a clean room in which a clean downdraft is continuously supplied, the contaminants P according to the process is generated in a very small amount. The contaminants P include organic contaminants. The contaminant P may be determined according to the type of process performed in the substrate treating operation S110. Alternatively, the contaminant P may be determined according to the material of the chamber in which the substrate treating operation S220 is performed.

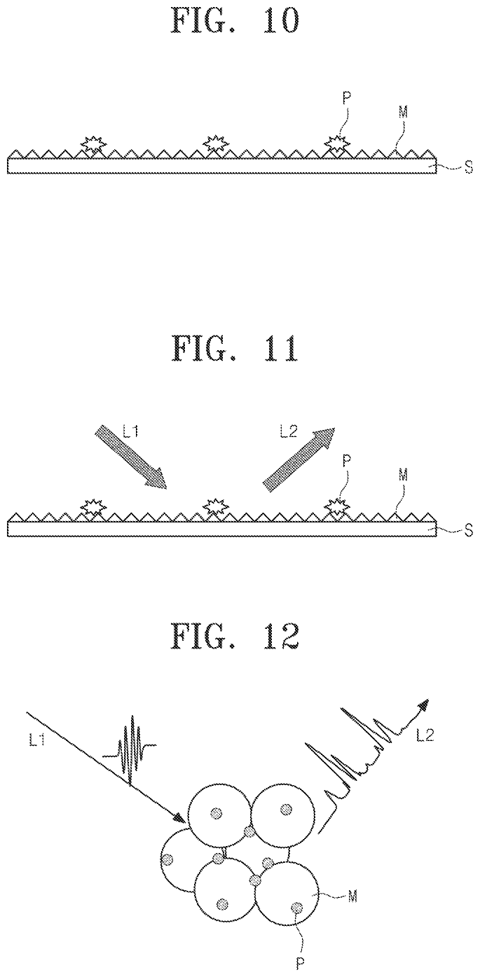

FIG. 10 is a view illustrating a state in which the contaminant P is adsorbed to the surface of the substrate S or the surface-enhanced Raman scattering layer M by the substrate treating operation of FIG. 8.

The contaminant analysis operation S230 is performed by Raman analysis. The contaminant analysis operation S230 is performed by Raman spectroscopy. The contaminant analysis operation S230 is performed by surface-enhanced Raman scattering spectroscopy. In the contaminant analysis operation S230, the molecular structure of the contaminant P may be analyzed. In addition, in the contaminant analysis operation S230, a component, a composition ratio of the contaminant P, or the degree of distribution of the contaminant P on the surface of the substrate S may be analyzed.

The contaminant analysis operation S230 includes is emitting first light L1 to the substrate S, detecting second light L2 generated from the contaminant P and amplified by the surface-enhanced Raman scattering layer M, and analyzing a component, a molar ratio of molecules, a molecular structure, and the like of the contaminant P by analyzing the second light L2.

Referring to FIGS. 11 and 12, the first light L1 is emitted to the substrate S. When the first light L1 is emitted, the first light L1 and the molecules of the contaminant P interact with each other, and photons of the first light L1 are scattered. At this time, the degree of scattering of the photons of the first light L1 varies according to the molecular identity of the molecules constituting the contaminant P, and the kinetic energy of the photons of the first light L1 is increased or decreased by scattering.

The first light L1 is changed into the second light L2 having different characteristics from the first light L2 by scattering. For example, the wavelength of the first light L2 may be different from the wavelength of the second light L2. In this case, the change in wavelength may be increased or decreased by the molecules constituting the contaminant P. A wavenumber of the first light L2 may be different from a wavenumber of the second light L2. The wavenumber means the reciprocal of the wavelength, and the change in the wavenumber may be increased or decreased by the molecules constituting the contaminant P. The energy of the first light L2 may be different from the energy of the second light L2. In this case, the change in energy may be increased or decreased by the molecules constituting the contaminant P.

In the second light L2, signals, such as wavelength, wavenumber, and energy, may be amplified by the surface-enhanced Raman scattering layer M. The second light L2 includes a Raman scattering signal, and accordingly, the second light L2 may be referred to as a Raman scattering signal. In addition, the Raman scattering signal is amplified by the surface-enhanced Raman scattering layer M, which may be referred to as a Raman scattering amplified signal.

In the contaminant analysis operation S230, the contaminant P is analyzed by detecting the second light L2 or a Raman scattering amplified signal from the second light L2. In the contaminant analysis operation S230, a component of a material constituting the contaminant P, a bonding structure of the contaminant P, etc. may be analyzed through the second light L2 or the Raman scattering amplified signal detected from the second light L2.

The first light L1 may be emitted to the substrate S by an optical system, such as a laser, and the second light L2 may be detected through a detector, such as a sensor. The analysis of the contaminant P may be performed through a controller (not illustrated). Configuration, storage and management of the controller may be realized in the form of hardware, software, or a combination of hardware and software. The file data and/or the software configuring the controller may be stored in volatile or non-volatile storage devices, such as Read Only Memory (ROM); or memory, such as, for example, Random Access Memory (RAM), memory chips, devices, or integrated circuits, or a storage medium, such as Compact Disk (CD), Digital Versatile Disc (DVD), magnetic disk, or magnetic tape, which are optically or magnetically recordable and simultaneously machine (for example, computer)-readable.

The particles adsorbed to the substrate greatly affect the yield of the device, and directly or indirectly affect the device and the element, such as causing a short circuit of the semiconductor device and deterioration or defect of a gate oxide film. Accordingly, in order to remove the contaminant P or control the generation of the contaminant P, an accurate analysis of the composition and structure of the contaminant P is required. For accurate analysis, it is necessary to amplify the intensity of a signal generated from the contaminant P.

According to the exemplary embodiment of the present invention, by introducing the surface-enhanced Raman scattering layer before and after the substrate treating operation S110, it is possible to amplify the Raman scattering signal generated from the contaminant P, and it is possible to accurately analyze the component, the molar ratio of the component material, the structure, the bonding structure, etc. of the contaminant P by Raman analysis through the Raman scattering amplified signal.

Through this analysis of the contaminant P, a chemical solution capable of effectively removing the contaminant P from the substrate S may be set. In addition, through the analysis of the contaminant P, it is possible to control whether the contaminant P is generated. For example, when the contaminant P is generated by a component of the processing liquid 82, the type of the processing liquid 82 may be changed, and when the contaminant P is generated from the material of the apparatus in which the substrate treatment is performed, the generation of the contaminant P may be controlled by changing the material of the apparatus.

Particles are divided into metal contaminants and organic contaminants according to the type of processing liquid used in the substrate treating process. Among the mentioned particles, various analysis devices and methods have been developed for metal contaminants, and it is possible to analyze metal contaminants present in trace amounts on a substrate.

The foregoing detailed description illustrates the present invention. In addition, the foregoing is intended to describe exemplary or various exemplary embodiments for implementing the technical spirit of the present invention, and the present invention may be used in various other combinations, changes, and environments. That is, the foregoing content may be modified or corrected within the scope of the concept of the invention disclosed in the present specification, the scope equivalent to that of the invention, and/or the scope of the skill or knowledge in the art. Accordingly, the detailed description of the invention above is not intended to limit the invention to the disclosed exemplary embodiment. In addition, the appended claims should be construed to include other exemplary embodiments as well. Such modified implementations should not be construed separately from the technical spirit or perspective of the present invention.

What is claimed is:

1. A method of analyzing contaminants adsorbed to a surface of a substrate, the method comprising:
a substrate treating operation of performing a process on a substrate;
an operation of introducing a surface-enhanced Raman scattering layer to the substrate having the surface to which a contaminant is adsorbed substrate in the substrate treating operation; and
an operation of analyzing the contaminant.

2. A method of analyzing contaminants adsorbed to a surface of a substrate, the method comprising:
an operation of introducing a surface-enhanced Raman scattering layer to a surface of a substrate;
a substrate treating operation of performing a process on the substrate to which the surface-enhanced Raman scattering layer is introduced; and
an operation of analyzing the contaminant adsorbed to the substrate in the substrate treating operation.

3. The method of claim 1, wherein the operation of analyzing the contaminant is performed by Raman analysis.

4. The method of claim 1, wherein the operation of analyzing the contaminant includes:
emitting first light to the substrate;
detecting second light generated from the contaminant and amplified by the surface-enhanced Raman scattering layer; and
analyzing the contaminant by analyzing the second light.

5. The method of claim 1, wherein in the operation of analyzing the contaminant, a molecular structure of the contaminant is analyzed.

6. The method of claim 1, wherein the surface-enhanced Raman scattering layer is formed by depositing a surface-enhanced Raman scattering material, and
the surface-enhanced Raman scattering material is provided as a metal material with high conductivity capable of generating surface plasmon excitation.

7. The method of claim 6, wherein the surface-enhanced Raman scattering material includes at least one of gold (Au), silver (Ag), aluminum (Al), copper (Cu), nickel (Ni), iron (Fe), cobalt (Co), zinc (Zn), titanium (Ti), ruthenium (Ru), rhodium (Rh), palladium (Pd), platinum (Pt), osmium (Os), iridium (Ir), and molybdenum (Mo).

8. The method of claim 6, wherein the surface-enhanced Raman scattering layer is provided in a nanostructure.

9. The method of claim 8, wherein the nanostructure includes any one of a nanoparticle, a nanorod, and a nanopattern.

10. The method of claim 1, wherein the contaminant is provided as an organic material.

11. The method of claim 1, wherein in the substrate treating operation, the substrate is treated by supplying a processing liquid to the substrate, and
the processing liquid is provided as a liquid containing an organic material.

12. The method of claim 1, wherein in the substrate treating operation, a photo process or a clean process is performed on the substrate.

13. The method of claim 1, wherein the substrate treating operation and the operation of introducing the surface-enhanced Raman scattering layer are performed in different chambers.

14. A method of treating a substrate, the method comprising:
treating a substrate by supplying a processing liquid to the substrate,
wherein before or after the treating of the substrate, a surface-enhanced Raman scattering layer is introduced by depositing a surface-enhanced Raman scattering material on a surface of the substrate.

15. The method of claim 14, wherein the surface-enhanced Raman scattering material is provided as a metal material with high conductivity capable of generating surface plasmon excitation.

16. The method of claim 15, wherein the surface-enhanced Raman scattering material includes at least one of gold (Au), silver (Ag), aluminum (Al), copper (Cu), nickel (Ni), iron (Fe), cobalt (Co), zinc (Zn), titanium (Ti), ruthenium (Ru), rhodium (Rh), palladium (Pd), platinum (Pt), osmium (Os), iridium (Ir), and molybdenum (Mo).

17. The method of claim 14, wherein the processing liquid is provided as a liquid containing an organic material.

18. The method of claim 17, wherein the treatment of the substrate includes photo processing or cleaning processing.

19. The method of claim 14, wherein the substrate treatment and the introduction of the surface-enhanced Raman scattering layer are performed in different chambers.

20. The method of claim 14, wherein a contaminant generated during the process of treating the substrate is adsorbed to the surface of the substrate or the surface-enhanced Raman scattering layer,
a structure of the contaminant is analyzed by Raman analysis, and
the surface-enhanced Raman scattering layer amplifies a Raman signal of the contaminant.
